(19) United States
(12) Patent Application Publication
(10) Pub. No.: US 2025/0234465 A1
(43) Pub. Date: Jul. 17, 2025

(54) VEHICULAR ELECTRIC POWER CONVERTING DEVICE

(71) Applicant: Mitsubishi Electric Corporation, Chiyoda-ku, Tokyo (JP)

(72) Inventor: Hirokazu Takabayashi, Chiyoda-ku, Tokyo (JP)

(73) Assignee: Mitsubishi Electric Corporation, Chiyoda-ku, Tokyo (JP)

(21) Appl. No.: 18/855,781

(22) PCT Filed: Jun. 7, 2022
(86) PCT No.: PCT/JP2022/022930

§ 371 Date: Oct. 10, 2024

(51) Int. Cl. H05K 5/02; B61C 3/00; B61C 17/00

(52) U.S. Cl. CPC H05K 5/0217; B61C 17/00; B61C 3/00

(57) ABSTRACT

A power converter includes a housing, an engagement member, and a guide. The housing accommodates a power conversion circuit. The engagement member is fixed to the housing. The guide is attachable under a floor of a vehicle body of a railway vehicle to extend in a width direction of the vehicle body. The guide has a shape engageable with the engagement member and supports the engagement member to allow movement of the engagement member in the width direction.

### TECHNICAL FIELD

The present disclosure relates to a vehicle power converter.

### BACKGROUND ART

A propulsion control device installable on a railway vehicle includes electronic circuits such as a power conversion circuit, a control circuit for controlling the power conversion circuit, a contactor, a detector, and a discharge circuit. These electronic circuits are accommodated in a housing. The housing of the propulsion control device has the volume to accommodate various electronic circuits described above and the strength to withstand vibration from a traveling railway vehicle, and is large and heavy. The propulsion control device thus has a large size and a heavy weight. To install a propulsion control device with a large size and a heavy weight on a railway vehicle, hangers fixed to the housing of the propulsion control device are attached under the floor of the vehicle body. Patent Literature 1 describes an example of such a propulsion control device. In Patent Literature 1, hanging parts fixed to the housing of an underfloor device are attached under the floor of a vehicle body with fasteners.

### CITATION LIST

### Patent Literature

Patent Literature 1: Unexamined Japanese Patent Application Publication No. 2014-15060

### SUMMARY OF INVENTION

### Technical Problem

For attaching the underfloor device described in Patent Literature 1 to the vehicle body, the underfloor device is first placed immediately below the vehicle body and lifted vertically upward, and then the hanging parts fixed to the housing of the underfloor device are attached to the vehicle body. For removing the underfloor device described in Patent Literature 1 from the vehicle body, the hanging parts are detached from the vehicle body while the underfloor device is supported from immediately below, and then the device is moved vertically downward.

A vehicle power converter installable on a railway vehicle has a large size and a heavy weight as described above, and is to be lifted and supported using a dolly cart. However, the dolly cart cannot be placed to immediately below the vehicle body from a lateral side of the railway vehicle because the railway vehicle is located on rails.

This involves the use of removable rails for the dolly cart to pass and an inspection facility such as an inspection pit with a space for placing the dolly cart immediately below the railway vehicle. The work of attaching or removing the above vehicle power converter to or from the vehicle body is thus complicated.

Under such circumstances, an objective of the present disclosure is to provide a vehicle power converter that is easily attachable to and removable from a vehicle body.

### Solution to Problem

To achieve the above objective, a vehicle power converter according to an aspect of the present disclosure is installable on a railway vehicle and includes a housing, an engagement member, and a guide. The housing accommodates a power conversion circuit. The engagement member is fixed to the housing. The guide is attachable under a floor of a vehicle body of the railway vehicle to extend in a width direction of the vehicle body. The guide has a shape engageable with the engagement member and supports the engagement member to allow movement of the engagement member in the width direction.

### Advantageous Effects of Invention

The vehicle power converter according to the above aspect of the present disclosure includes the engagement member fixed to the housing and the guide attachable under the floor of the vehicle body of the railway vehicle to extend in the width direction of the vehicle body. The guide supports the engagement member fixed to the housing to allow movement of the engagement member in the width direction. The vehicle power converter is thus easily attachable to and removable from the vehicle body.

### BRIEF DESCRIPTION OF DRAWINGS

FIG. 1 is a circuit diagram illustrating a propulsion control device in an embodiment;

FIG. 2 illustrates a railway vehicle provided with a vehicle power converter according to the embodiment;

FIG. 3 illustrates a railway vehicle provided with the vehicle power converter according to the embodiment;

FIG. 4 is a perspective view of the vehicle power converter according to the embodiment;

FIG. 5 illustrates movement of a housing of the vehicle power converter according to the embodiment;

FIG. 6 illustrates movement of the housing of the vehicle power converter according to the embodiment;

FIG. 7 illustrates a railway vehicle provided with a vehicle power converter according to a first modification of the embodiment;

FIG. 8 is a perspective view of the vehicle power converter according to the first modification of the embodiment;

FIG. 9 is a perspective view of a vehicle power converter according to a second modification of the embodiment;

FIG. 10 is a perspective view of a vehicle power converter according to a third modification of the embodiment;

FIG. 11 illustrates movement of a housing of the vehicle power converter according to the third modification of the embodiment;

FIG. 12 is a perspective view of a vehicle power converter according to a fourth modification of the embodiment;

FIG. 13 is a cross-sectional view of a vehicle power converter according to a fifth modification of the embodiment; and

FIG. 14 is a cross-sectional view of a vehicle power converter according to a sixth modification of the embodiment.

### DESCRIPTION OF EMBODIMENTS

An electronic device according to one or more embodiments of the present disclosure is described below in detail with reference to the drawings. Components identical or corresponding to each other are provided with the same reference sign in the drawings.

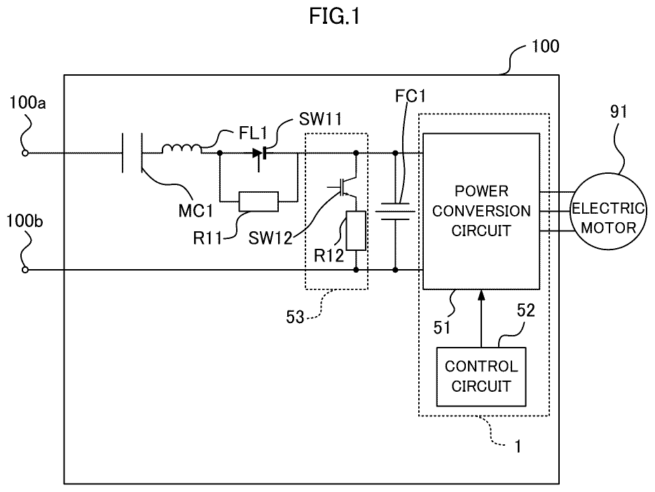

An example electronic device installable on a railway vehicle is a propulsion control device installable on a railway vehicle to convert direct current (DC) power supplied from a DC power supply to alternating current (AC) power to be supplied to a load and to supply the resulting AC power to an electric motor. A propulsion control device 100 illustrated in FIG. 1 is installable on a DC feeding railway vehicle. The propulsion control device 100 converts supplied DC power to AC power to be supplied to an electric motor 91, and supplies the resulting AC power to the electric motor 91. The electric motor 91 is, for example, a three-phase induction motor that generates propulsion of the railway vehicle.

The propulsion control device 100 includes a terminal 100a that is connected to a power supply, or more specifically, a current collector and a terminal 100b that is grounded. The current collector receives power from an electrical substation through a power line. For example, the current collector is a pantograph or a current collector shoe, and the power line is an overhead power line or a third rail.

The propulsion control device 100 further includes a power conversion circuit 51 that converts direct current (DC) power supplied from the power supply to alternating current (AC) power, and a control circuit 52 that controls switching elements in the power conversion circuit 51. The power conversion circuit 51 and the control circuit 52 are collectively referred to as a power converter 1.

The propulsion control device 100 further includes a contactor MC1 having one end connected to the terminal 100a, a filter reactor FL1 having one end connected to the contactor MC1, a first switch SW11 having one end connected to the other end of the filter reactor FL1 and having the other end connected to the power conversion circuit 51. The propulsion control device 100 further includes a charging resistor R11 connected in parallel to the first switch SW11, a filter capacitor FC1 connected between primary terminals of the power conversion circuit 51, or more specifically, between terminals near the power supply, and a discharge circuit 53 connected in parallel to the filter capacitor FC1. The discharge circuit 53 includes a second switch SW12 and a discharge resistor R12 that are connected in series.

The contactor MC1 is located between the power conversion circuit 51 and the power source to open and close an electric path. The contactor MC1 is a DC electromagnetic contactor that is turned on or off by a contactor controller, which is not illustrated. When turned on, the contactor MC1 electrically connects the terminal 100a to the filter reactor FL1. The power conversion circuit 51 is thus electrically connected to the power source. When turned off, the contactor MC1 electrically disconnects the terminal 100a from the filter reactor FL1. The power conversion circuit 51 is thus electrically disconnected from the power source.

The filter reactor FL1 and the filter capacitor FC1 together serve as an inductor-capacitor (LC) filter to reduce harmonic components generated by switching of the power conversion circuit 51. The filter reactor FL1 also reduces, for example, ripple voltage in an output from electronic components including a rectifier in the electrical substation.

The first switch SW11 is turned on or off by a switch controller, which is not illustrated. When the contactor MC1 is turned on with the first switch SW11 being on, a current flows from the terminal 100a, through the contactor MC1, the filter reactor FL1, and the first switch SW11, and to the power conversion circuit 51 and the filter capacitor FC1. When the contactor MC1 is turned on with the first switch SW11 being off, a current flows from the terminal 100a, through the contactor MC1, the filter reactor FL1, and the charging resistor R11, and to the power conversion circuit 51 and the filter capacitor FC1. The first switch SW11 is, for example, a thyristor.

The charging resistor R11 suppresses the likelihood that an inrush current flows through the power conversion circuit 51 at the start of the operation of the propulsion control device 100. The resistance value of the charging resistor R11 is set to suppress the likelihood that an inrush current flows through the power conversion circuit 51.

The filter capacitor FC1 is located between the primary terminals of the power conversion circuit 51 and charged with the DC power supplied from the power source.

The power conversion circuit 51 converts the DC power supplied through the filter capacitor FC1 to three-phase AC power and outputs the three-phase AC power to the electric motor 91. The voltage and frequency of the three-phase AC power output by the power conversion circuit 51 are adjustable. The power conversion circuit 51 includes multiple switching elements such as insulated-gate bipolar transistors (IGBTs) and converts the DC power to the three-phase AC power with switching of IGBTs.

Upon receiving an operation command instructing the propulsion control device 100 to operate or stop, the control circuit 52 generates control signals for controlling the switching elements included in the power conversion circuit 51 in accordance with the operation command and transmits the control signals to the switching elements included in the power conversion circuit 51, or more specifically, to the gate terminals of the IGBTs. The control circuit 52 is, for example, a gate driver board.

The second switch SW12 in the discharge circuit 53 is controlled by the switch controller. When the second switch SW12 is turned on with the contactor MC1 being off, the discharge resistor R12 is electrically connected to the filter capacitor FC1 to discharge the filter capacitor FC1. With the second switch SW12 being off, the discharge resistor R12 is electrically disconnected from the filter capacitor FC1.

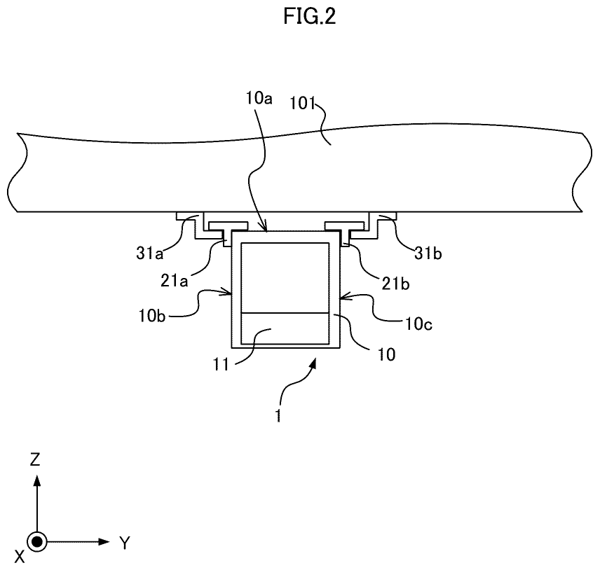

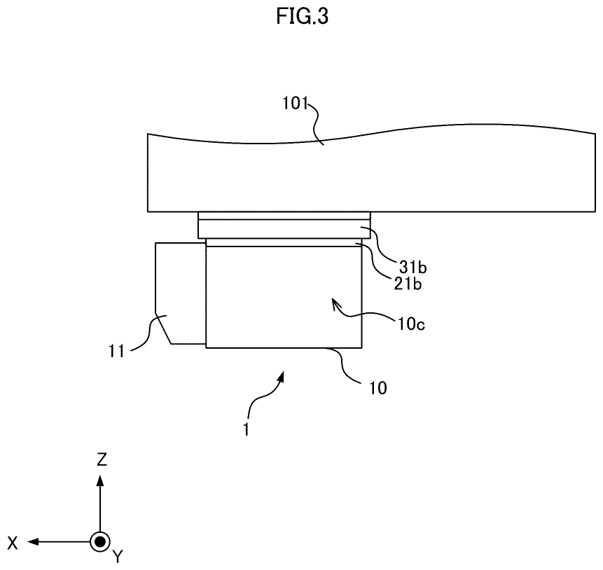

Of the components of the propulsion control device 100 described above, the power converter 1 is accommodated in a housing separate from the housing accommodating the other components. More specifically, in addition to the power conversion circuit 51 and the control circuit 52 illustrated in FIG. 1, the power converter 1 includes, as illustrated in FIGS. 2 and 3, a housing 10 accommodating the power conversion circuit 51 and the control circuit 52 and a cooler 11 attached to the housing 10 and thermally connected to the power conversion circuit 51 and the control circuit 52. The housing 10 is attached under the floor of a vehicle body 101 of a railway vehicle. In FIGS. 2 and 3, an X-axis indicates the width direction of the vehicle body 101, and a Y-axis indicates the traveling direction of the railway vehicle. The X-axis, the Y-axis, and a Z-axis are perpendicular to one another. The Z-axis indicates the vertical direction when the railway vehicle is located horizontally. The same applies to subsequent figures.

The housing 10 is formed from a material that is rigid enough to resist deformation under the vibration generated by the travelling railway vehicle. The housing 10 may preferably be formed from a highly thermally conductive material, for example, a metal material. The housing 10 formed from a highly thermally conductive material can transfer heat from the electronic components in the power conversion circuit 51 and the control circuit 52 accommodated in the housing 10 to air outside the housing 10 to cool the electronic components. The housing 10 is formed from, for example, aluminum.

The housing 10 may preferably be waterproof and dustproof. This suppresses entry of, for example, dust and water into the housing 10. Thus, the power conversion circuit 51 and the control circuit 52 accommodated in the housing 10 are less likely to come in contact with, for example, dust and water.

The cooler 11 includes, for example, a heat pipe, fins, and a cover covering the heat pipe and the fins. The cooler 11 dissipates heat transferred from the power conversion circuit 51 and the control circuit 52 to ambient air. The power conversion circuit 51 and the control circuit 52 are thus cooled.

The power converter 1 further includes members for removably attaching the housing 10 to the vehicle body 101. More specifically, as illustrated in FIGS. 2 to 4, the power converter 1 includes a pair of columns 21a and 21b fixed to the housing 10 to serve as engagement members, and a pair of guide rails 31a and 31b attachable under the floor of the vehicle body 101 to extend in the width direction of the vehicle body 101, or more specifically, in the X-axis direction, to serve as guides.

The propulsion control device 100 weighs about 500 kg. The overall weight of the power converter 1 that is part of the propulsion control device 100 is, for example, about 150 kg. Thus, the guides, or more specifically, the guide rails 31a and 31b, attachable under the floor of the vehicle body 101 may have the rigidity and structure to withstand a weight greater than the overall weight of the power converter 1 that may be, for example, 200 kg.

The columns 21a and 21b extend in the X-axis direction and have a T-shaped cross section perpendicular to the X-axis direction. The columns 21a and 21b are formed from a material that is rigid enough to resist deformation under the vibration generated by the travelling railway vehicle, for example, a metal material. In one example, the columns 21a and 21b are formed from aluminum by extrusion molding. The columns 21a and 21b each have a flat plate portion extending in the X-axis direction and Y-axis direction and a flat plate portion extending in the X-axis direction and Z-axis direction. The thickness in the Z-axis direction of the flat plate portion extending in the X-axis direction and Y-axis direction and the thickness in the Y-axis direction of the flat plate portion extending in the X-axis direction and Z-axis direction are each, for example, 15 to 20 mm inclusive.

The engagement members are each fixed to at least one of a vertically upward surface of the housing 10 or surfaces of the housing 10 intersecting with the traveling direction of the railway vehicle. In the embodiment, the column 21a is fixed to the vertically upward surface of the housing 10, or more specifically, a surface 10a facing in the positive Z-axis direction, and to a surface intersecting with the traveling direction of the railway vehicle, or more specifically, a surface 10b facing in the negative Y-axis direction. In the embodiment, the column 21a is fixed to the housing 10 with one of the surfaces of the column 21a facing in the negative Z-axis direction in contact with the surface 10a of the housing 10 and with the surface of the flat plate portion of the column 21a extending in the X-axis direction and Z-axis direction facing in the positive Y-axis direction in contact with the surface 10b of the housing 10.

The column 21b is fixed to the surface 10a facing in the positive Z-axis direction and to a surface intersecting with the traveling direction of the railway vehicle, or more specifically, to a surface 10c facing in the positive Y-axis direction. In the embodiment, the column 21b is fixed to the housing 10 with one of the surfaces of the column 21b facing in the negative Z-axis direction in contact with the surface 10a of the housing 10 and with the surface of the flat plate portion of the column 21b extending in the X-axis direction and Z-axis direction facing in the negative Y-axis direction in contact with the surface 10c of the housing 10.

The columns 21a and 21b are fixed to the housing 10 firmly enough to maintain the positional relationship of the columns 21a and 21b relative to the housing 10 under the vibration generated by the traveling railway vehicle. The columns 21a and 21b are fixed to the housing 10 by, for example, fastening with a fastener, welding, or brazing.

The other surface of each of the columns 21a and 21b facing in the negative Z-axis direction engages with the guide rail 31a or 31b. More specifically, the other surface of each of the columns 21a and 21b facing in the negative Z-axis direction is in surface contact with the surface of the guide rail 31a or 31b facing in the positive Z-axis direction and supported by the guide rail 31a or 31b.

The guide rails 31a and 31b are formed from a material that is rigid enough to resist deformation under the vibration generated by the travelling railway vehicle, for example, a metal material. In one example, the guide rails 31a and 31b are formed from aluminum by a processing method such as extrusion molding or bending. The guide rails 31a and 31b are formed by bending a flat plate with a thickness of, for example, 15 to 20 mm inclusive.

One end of the guide rail 31a closer to the vehicle body 101 is fixed to the vehicle body 101. One end of the guide rail 31b closer to the vehicle body 101 is fixed to the vehicle body 101. The ends of the guide rails 31a and 31b closer to the vehicle body 101 are fixed to the vehicle body 101 firmly enough to maintain the positional relationship of the guide rails 31a and 31b relative to the vehicle body 101 under the vibration generated by the traveling railway vehicle. The guide rails 31a and 31b are fixed to the vehicle body 101 by a fixing method such as fastening with a fastener, welding, or brazing.

The other end of the guide rail 31a farther from the vehicle body 101 is located apart from the vehicle body 101 and supports the column 21a. More specifically, the surface of the other end of the guide rail 31a facing in the positive Z-axis direction is in surface contact with a surface of the column 21a and supports the column 21a to allow movement of the column 21a in the X-axis direction. The other end of the guide rail 31b farther from the vehicle body 101 supports the column 21b. More specifically, the surface of the other end of the guide rail 31b facing in the positive Z-axis direction is in surface contact with a surface of the column 21b and supports the column 21b to allow movement of the column 21b in the X-axis direction.

In the embodiment, the guide rail 31a includes a flat plate portion extending in the X-axis direction and Z-axis direction and two flat plate portions extending in the X-axis direction and Y-axis direction and located opposite to each other with the flat plate portion extending in the X-axis direction and Z-axis direction between the two flat plate portions. Of the two flat plate portions in the guide rail 31a extending in the X-axis direction and Y-axis direction, one is fixed to the vehicle body 101, and the other is located apart from the vehicle body 101 and supports the column 21a located between the vehicle body 101 and the other flat plate portion to allow movement of the column 21a in the X-axis direction.

The guide rail 31b includes a flat plate portion extending in the X-axis direction and Z-axis direction and two flat plate portions extending in the X-axis direction and Y-axis direction and located opposite to each other with the flat plate portion extending in the X-axis direction and Z-axis direction between the two flat plate portions. Of the two flat plate portions in the guide rail 31b extending in the X-axis direction and Y-axis direction, one is fixed to the vehicle body 101, and the other is located apart from the vehicle body 101 and supports the column 21b located between the vehicle body 101 and the other flat plate portion to allow movement of the column 21b in the X-axis direction.

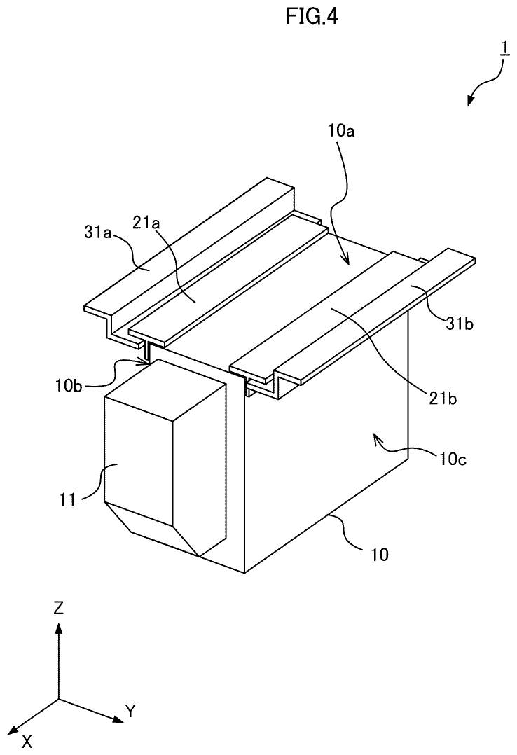

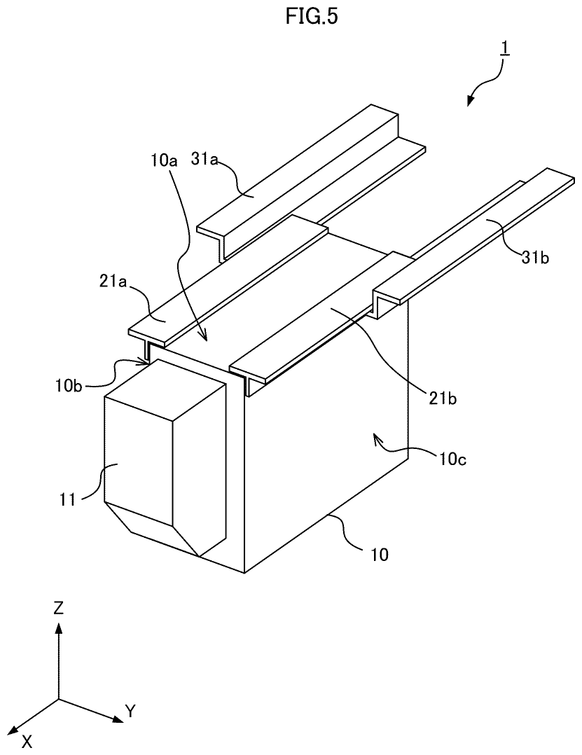

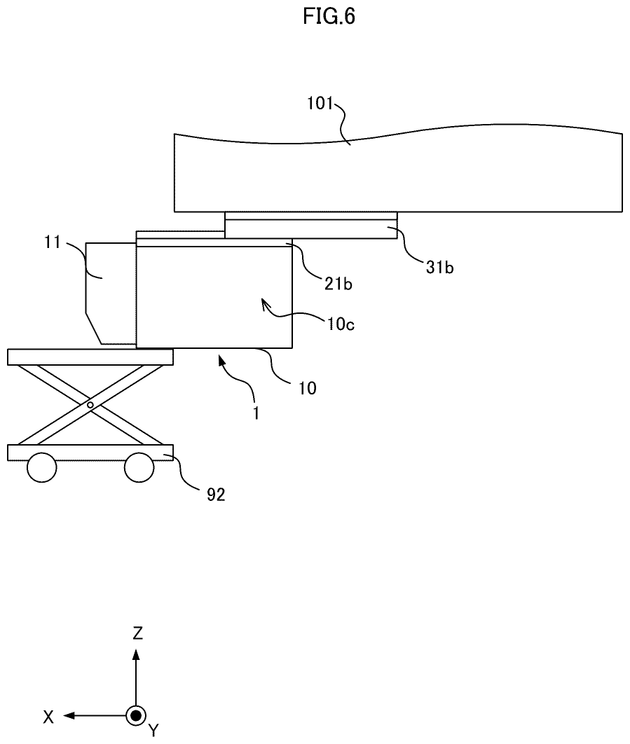

The guide rails 31a and 31b, supporting the columns 21a and 21b fixed to the housing 10 to allow movement of the columns 21a and 21b in the X-axis direction, allow the housing 10 at the position illustrated in FIGS. 3 and 4 to be pulled out in the positive X-axis direction to the position illustrated in FIGS. 5 and 6. This facilitates removal of the power converter 1 from the vehicle body 101. The housing 10 pulled out in the positive X-axis direction is supported by a dolly cart 92. The housing 10 pulled out in the X-axis direction does not need the dolly cart 92 located vertically below the vehicle body 101. This eliminates, for removing the housing 10, the use of removable rails for the dolly cart 92 to pass and an inspection facility such as an inspection pit with a space for placing the dolly cart 92 immediately below the railway vehicle.

The housing 10 is attached by engaging the columns 21a and 21b fixed to the housing 10 supported by the dolly cart 92 with the ends of the guide rails 31a and 31b and then sliding the housing 10 in the negative X-axis direction. Thus, the columns 21a and 21b engaged with the guide rails 31a and 31b can move in the negative X-axis direction to place the housing 10 immediately below the vehicle body 101, as illustrated in FIGS. 3 and 4. This facilitates attachment of the power converter 1 to the vehicle body 101. In this state, the columns 21a and 21b fixed to the housing 10 move in the negative X-axis direction on the guide rails 31a and 31b. The dolly cart 92 is thus not moved to vertically below the vehicle body 101. This eliminates, for attaching the housing 10, the use of removable rails for the dolly cart 92 to pass and an inspection facility such as an inspection pit with a space for placing the dolly cart 92 immediately below the railway vehicle.

The housing 10 located as illustrated in FIGS. 3 and 4 may preferably be restricted from moving in the X-axis direction. For example, a non-illustrated fixing members fixed to the guide rails 31a and 31b in contact with the ends of the columns 21a and 21b in the positive X-axis direction may preferably be used to restrict the movement of the columns 21a and 21b in the X-axis direction. This restricts the movement of the housing 10 in the X-axis direction when the railway vehicle travels.

To reduce the workload for removing or attaching the housing 10 as described above, the coefficients of friction may preferably be low between the contact surfaces of the column 21a and the guide rail 31a and between the contact surfaces of the column 21b and the guide rail 31b. For example, the surfaces of the guide rails 31a and 31b in contact with the columns 21a and 21b may preferably be coated with resin for smooth movement of the columns 21a and 21b in the X-axis direction.

As described above, in the power converter 1 according to the embodiment, the columns 21a and 21b are movable in the X-axis direction on the guide rails 31a and 31b. This allows the housing 10 to be pulled out to the lateral side of the vehicle body 101 and allows the housing 10 to be moved to vertically below the vehicle body 101 from the lateral side of the vehicle body 101. Thus, the power converter 1 is easily attachable to and removable from the vehicle body 101.

As described above, the housing 10 can be pulled out to the lateral side of the vehicle body 101 and can be moved to vertically below the vehicle body 101 from the lateral side of the vehicle body 101. This eliminates the use of removable rails for the dolly cart 92 to pass and an inspection facility such as an inspection pit with a space for placing the dolly cart 92 immediately below the railway vehicle. In other words, the housing 10 can be attached to or removed from the vehicle body at any place with no inspection facility.

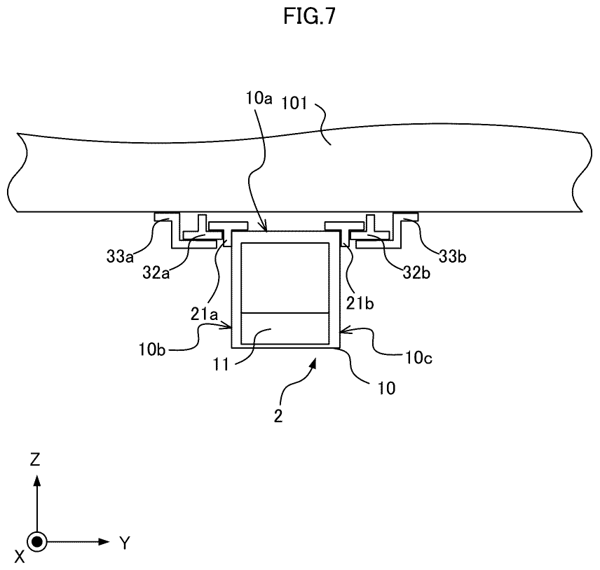

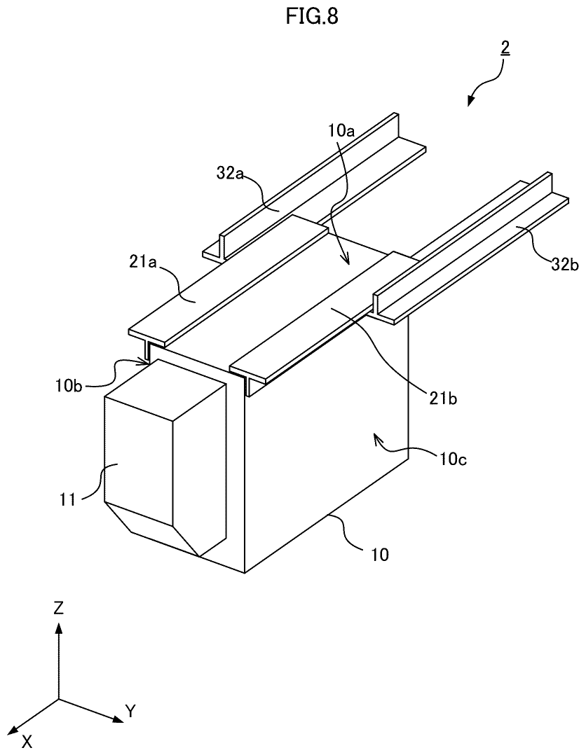

The present disclosure is not limited to the above embodiment. The shapes of the engagement members and the guides are not limited to the above examples. FIGS. 7 and 8 illustrate an example of a power converter 2 including guides with a structure different from the structure in the embodiment. Similarly to the power converter 1, the power converter 2 includes a pair of columns 21a and 21b that serve as engagement members fixed to the housing 10. The power converter 2 includes a pair of guide rails 32a and 32b attachable under the floor of the vehicle body 101 and serving as guides extending in the X-axis direction, and a pair of frames 33a and 33b attachable to the vehicle body 101 and to which the guide rails 32a and 32b are fixed. For ease of illustration, the frames 33a and 33b are not illustrated in FIG. 8.

The guide rails 32a and 32b extend in the X-axis direction and have a T shape, or more specifically, a T shape rotated by 180 degrees, in a cross section perpendicular to the X-axis direction. For example, the guide rails 32a and 32b have the same shape as the columns 21a and 21b in the power converter 1. The guide rails 32a and 32b are formed from a material that is rigid enough to resist deformation under the vibration generated by the travelling railway vehicle, for example, a metal material. In one example, the guide rails 32a and 32b are formed from aluminum by extrusion molding, similarly to the columns 21a and 21b.

One of the surfaces of the guide rail 32a facing in the positive Z-axis direction is in surface contact with the column 21a as in the embodiment, and supports the column 21a to allow movement of the column 21a in the X-axis direction. One of the surfaces of the guide rail 32b facing in the positive Z-axis direction is in surface contact with the column 21b as in the embodiment, and supports the column 21b to allow movement of the column 21b in the X-axis direction.

The guide rail 32a is fixed to the frame 33a with the surface of the guide rail 32a facing in the negative Z-axis direction at least partially in contact with the frame 33a. The guide rail 32a is fixed to the frame 33a firmly enough to maintain the positional relationship of the guide rail 32a relative to the frame 33a under the vibration generated by the traveling railway vehicle.

The guide rail 32b is fixed to the frame 33b with the surface of the guide rail 32b facing in the negative Z-axis direction at least partially in contact with the frame 33b. The guide rail 32b is fixed to the frame 33b firmly enough to maintain the positional relationship of the guide rail 32b relative to the frame 33b under the vibration generated by the traveling railway vehicle.

The guide rails 32a and 32b are fixed to the frame 33a and 33b by a fixing method such as fastening with a fastener, welding, or brazing.

The frames 33a and 33b extend in the X-axis direction. For example, the frames 33a and 33b have the same shape as the guide rails 31a and 31b in the power converter 1. One end of the frame 33a closer to the vehicle body 101 is fixed to the vehicle body 101. The other end of the frame 33a farther from the vehicle body 101 is fixed to the guide rail 32a. The end of the frame 33a closer to the vehicle body 101 is fixed to the vehicle body 101 firmly enough to maintain the positional relationship of the frame 33a relative to the vehicle body 101 under the vibration generated by the traveling railway vehicle.

One end of the frame 33b closer to the vehicle body 101 is fixed to the vehicle body 101. The other end of the frame 33b farther from the vehicle body 101 is fixed to the guide rail 32b. The end of the frame 33b closer to the vehicle body 101 is fixed to the vehicle body 101 firmly enough to maintain the positional relationship of the frame 33b relative to the vehicle body 101 under the vibration generated by the traveling railway vehicle.

The frames 33a and 33b are fixed to the vehicle body 101 by a fixing method such as fastening with a fastener, welding, or brazing.

The housing 10 in the power converter 2 can also be pulled out in the X-axis direction, as illustrated in FIG. 8.

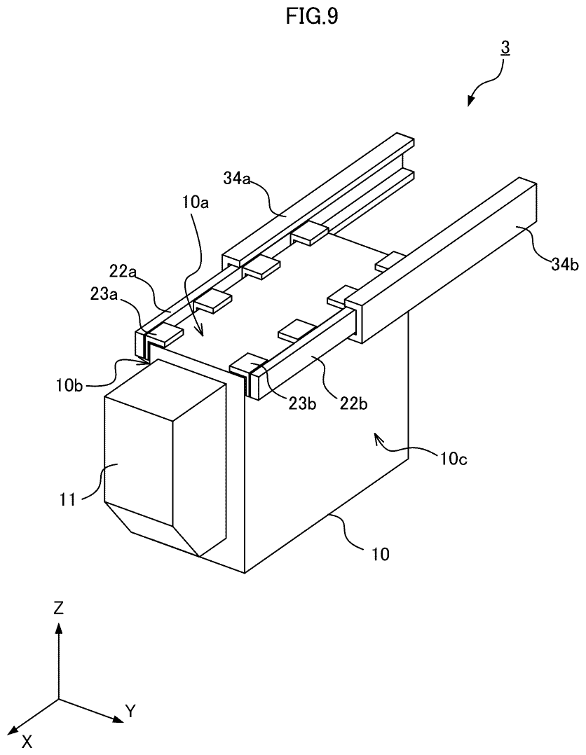

FIG. 9 illustrates an example of a power converter 3 including engagement members and guides with structures different from the structures in the embodiment. The power converter 3 includes columns 22a and 22b and multiple hangers 23a and 23b that serve as engagement members fixed to the housing 10, and a pair of guide rails 34a and 34b to serve as guides. Not illustrated, but the power converter 3 further includes the frames 33a and 33b included in the power converter 2.

The hangers 23a each have an L shape, or more specifically, an L shape rotated by 90 degrees, in a cross section perpendicular to the X-axis direction. The hangers 23a are aligned at intervals in the X-axis direction. The hangers 23b each have an L shape, or more specifically, an L shape rotated by 90 degrees, in a cross section perpendicular to the X-axis direction. The hangers 23b are aligned at intervals in the X-axis direction. In the example in FIG. 9, four hangers 23a are aligned at equal intervals in the X-axis direction, and four hangers 23b are aligned at equal intervals in the X-axis direction.

Each hanger 23a is fixed to the surfaces 10a and 10b of the housing 10. Each hanger 23b is fixed to the surfaces 10a and 10c of the housing 10. The hangers 23a and 23b are fixed to the housing 10 firmly enough to maintain the positional relationship of the hangers 23a and 23b relative to the housing 10 under the vibration generated by the traveling railway vehicle. The hangers 23a and 23b are fixed to the housing 10 by a fixing method such as fastening with a fastener, welding, or brazing.

The columns 22a and 22b extend in the X-axis direction and each have a rectangular or square cross section perpendicular to the X-axis direction. The column 22a is in contact with the surface of each hanger 23a facing in the negative Y-axis direction and is fixed to the hangers 23a. The column 22b is in contact with the surface of each hanger 23b facing in the positive Y-axis direction and is fixed to the hangers 23b. The columns 22a and 22b are fixed to the hangers 23a and 23b firmly enough to maintain the positional relationship of the columns 22a and 22b relative to the hangers 23a and 23b under the vibration generated by the traveling railway vehicle. The columns 22a and 22b are fixed to the hangers 23a and 23b by a fixing method such as fastening with a fastener, welding, or brazing

The guide rails 34a and 34b, with a shape engageable with the columns 22a and 22b, extend in the X-axis direction and support the columns 22a and 22b to allow movement of the columns 22a and 22b in the X-axis direction. In one example, the guide rail 34a is a column extending in the X-axis direction and having a groove that is open in the positive Y-axis direction. Similarly, the guide rail 34b is a column extending in the X-axis direction and having a groove that is open in the negative Y-axis direction. The guide rail 34a and the column 22a can be heavy duty slide rails for moving heavy objects. The guide rail 34b and the column 22b can be heavy duty slide rails for moving heavy objects.

The guide rails 34a and 34b may be fixed to the frames 33a and 33b, and may be fixed to the vehicle body 101 with the frames 33a and 33b.

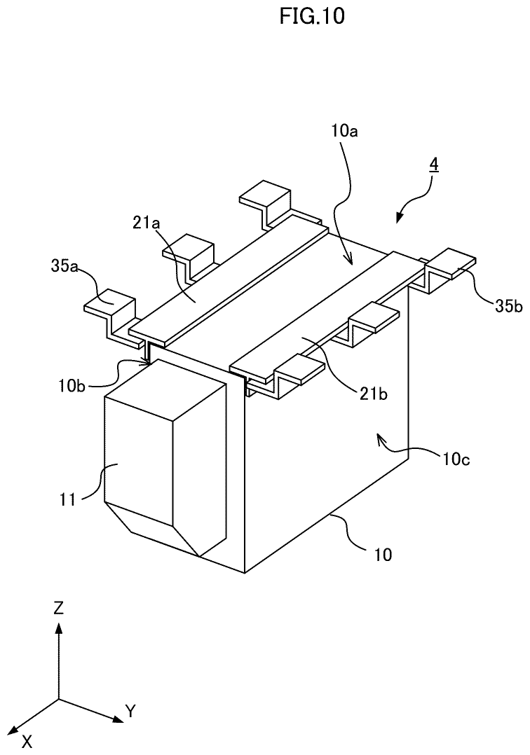

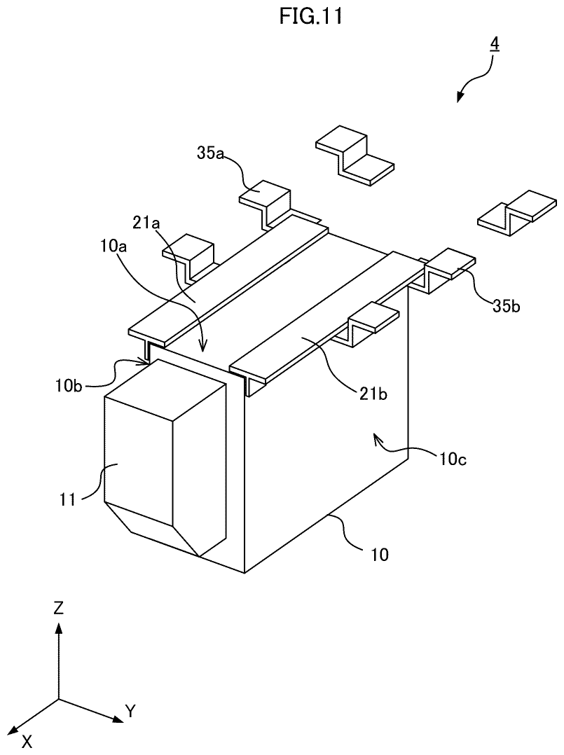

FIGS. 10 and 11 illustrate an example of a power converter 4 including guides with a structure different from the structure in the embodiment. Similarly to the power converter 1, the power converter 4 includes a pair of columns 21a and 21b that serve as engagement members fixed to the housing 10. The power converter 4 includes multiple supports 35a and 35b attachable under the floor of the vehicle body 101. The supports 35a and 35b serve as guides extending in the width direction of the vehicle body 101, or more specifically, in the X-axis direction.

The supports 35a and 35b have the same shape as the guide rails 31a and 31b in the power converter 1 in a cross section perpendicular to the X-axis direction. The supports 35a are aligned at intervals in the X-axis direction. The supports 35b are aligned at intervals in the X-axis direction.

One end of each support 35a closer to the vehicle body 101 is fixed to the vehicle body 101. More specifically, the end of each support 35a closer to the vehicle body 101 is fixed to the vehicle body 101 firmly enough to maintain the positional relationship of the support 35a relative to the vehicle body 101 under the vibration generated by the traveling railway vehicle.

One end of each support 35b closer to the vehicle body 101 is fixed to the vehicle body 101. More specifically, the end of each support 35b closer to the vehicle body 101 is fixed to the vehicle body 101 firmly enough to maintain the positional relationship of the support 35b relative to the vehicle body 101 under the vibration generated by the traveling railway vehicle.

The supports 35a and 35b are fixed to the vehicle body 101 by a fixing method such as fastening with a fastener, welding, or brazing.

The other end of each support 35a supports the column 21a. More specifically, the surface of the other end of each support 35a facing in the positive Z-axis direction is in surface contact with the column 21a and supports the column 21a to allow movement of the column 21a in the X-axis direction. The other end of each support 35b supports the column 21b. More specifically, the surface of the other end of each support 35b facing in the positive Z-axis direction is in surface contact with the column 21b and supports the column 21b to allow movement of the column 21b in the X-axis direction.

The supports 35a and 35b may be aligned at any intervals that allow the housing 10 pulled out in the X-axis direction to be supported, as illustrated in FIG. 11. In the example in FIGS. 10 and 11, three supports 35a are aligned at equal intervals in the X-axis direction, and three supports 35b are aligned at equal intervals in the X-axis direction.

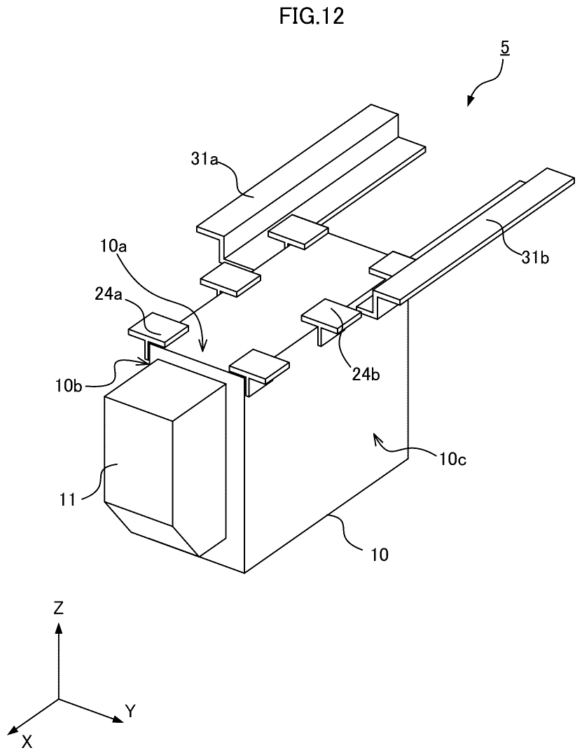

FIG. 12 illustrates an example of a power converter 5 including engagement members with a structure different from the structure in the embodiment. The power converter 5 includes multiple hangers 24a and 24b that serve as engagement members fixed to the housing 10. Similarly to the power converter 1, the power converter 5 includes multiple guide rails 31a and 31b attachable under the floor of the vehicle body 101 to serve as guides extending in the width direction of the vehicle body 101, or more specifically, in the X-axis direction.

The hangers 24a and 24b have the same shape as the columns 21a and 21b in the power converter 1 in a cross section perpendicular to the X-axis direction. The hangers 24a are aligned at intervals in the X-axis direction. The hangers 24b are aligned at intervals in the X-axis direction. In the example in FIG. 12, three hangers 24a are aligned at equal intervals in the X-axis direction, and three hangers 24b are aligned at equal intervals in the X-axis direction.

Each hanger 24a is fixed to the surfaces 10a and 10b of the housing 10. Each hanger 24b is fixed to the surfaces 10a and 10c of the housing 10. The hangers 24a and 24b are fixed to the housing 10 firmly enough to maintain the positional relationship of the hangers 24a and 24b relative to the housing 10 under the vibration generated by the traveling railway vehicle. The hangers 24a and 24b are fixed to the housing 10 by a fixing method such as fastening with a fastener, welding, or brazing.

Similarly to the column 21a in the power converter 1, the hangers 24a are supported by the guide rail 31a in a manner movable in the X-axis direction. Similarly to the column 21b in the power converter 1, the hangers 24b are supported by the guide rail 31b in a manner movable in the X-axis direction.

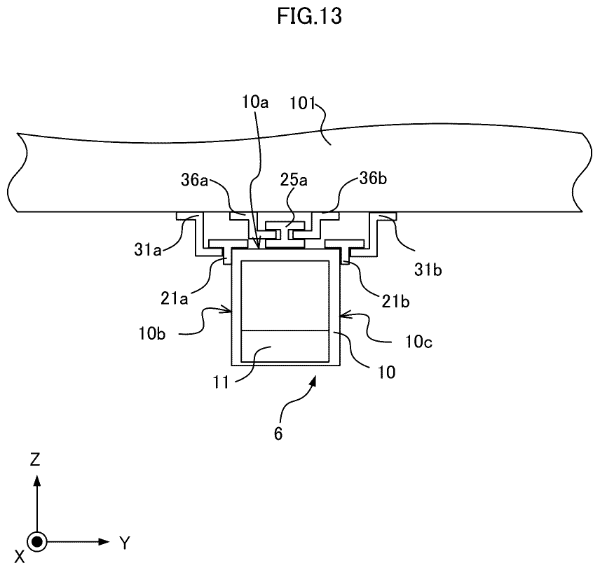

The number of components serving as engagement members is not limited to the above examples. In one example, FIG. 13 illustrates a power converter 6 that further includes, in addition to the components of the power converter 1, a column 25a fixed to the surface 10a of the housing 10 in the middle of the surface 10a in the Y-axis direction and guide rails 36a and 36b with shapes engageable with the column 25a. The column 25a extends in the X-axis direction and has an H shape, or more specifically, an H shape rotated by 90 degrees, in a cross section perpendicular to the X-axis direction. The column 25a is located between the columns 21a and 21b. The column 25a is fixed to the surface 10a of the housing 10 in the middle of the surface 10a in the Y-axis direction.

Similarly to the guide rails 31a and 31b, each of the guide rails 36a and 36b includes a flat plate portion extending in the X-axis direction and Z-axis direction and two flat plate portions extending in the X-axis direction and Y-axis direction and located opposite to each other with the flat plate portion extending in the X-axis direction and Z-axis direction between the two flat plate portions. The guide rails 36a and 36b support the column 25a to allow movement of the column 25a in the X-axis direction. Similarly, the power converters 2 to 5 may further include the column 25a and the guide rails 36a and 36b.

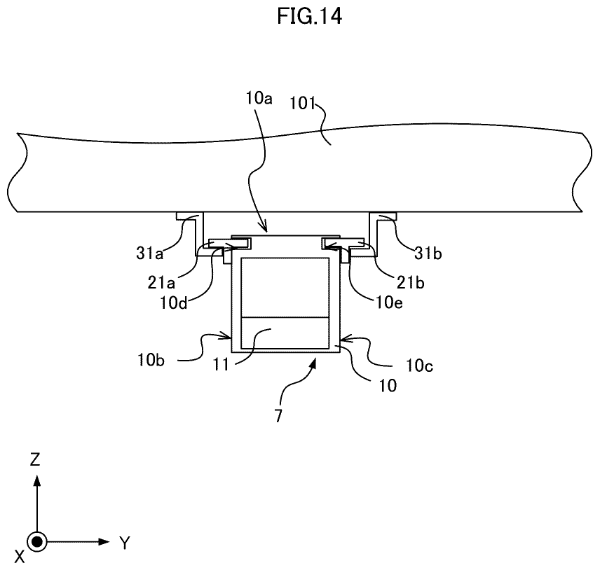

The engagement members may each be fixed simply to one of the vertically upward surface of the housing 10 and surfaces of the housing 10 intersecting with the traveling direction of the railway vehicle. FIG. 14 illustrates an example of a power converter 7 including columns 21a and 21b each fixed simply to the surface 10b or 10c. The surface 10b of the housing 10 in the power converter 7 has a groove 10d extending in the X-axis direction. The surface 10c has a groove 10e extending in the X-axis direction. The columns 21a is received in the groove 10d and fixed to the surface 10b by, for example, fastening with a fastener. The columns 21b is received in the groove 10e and fixed to the surface 10c by, for example, fastening with a fastener.

The numbers and the positions of the hangers 23a and 23b in FIG. 9 are not limited to the above example. The hangers 23a and 23b may be located at any positions that allow the columns 22a and 22b to be fixed to the housing 10. In one example, the hangers 23a may be aligned at unequal intervals in the X-axis direction, and the hangers 23b may be aligned at unequal intervals in the X-axis direction.

Any number of hangers 24a and 24b illustrated in FIG. 12 are at any positions when the hangers 24a and 24b are located at least at the two ends of the housing 10 in the X-axis direction. In one example, the hangers 24a may be located simply at the two ends in the X-axis direction of the housing 10, and the hangers 24b may be located simply at the two vertical ends of the housing 10.

Any number of supports 35a and 35b illustrated in FIGS. 10 and 11 are at any positions when the supports 35a and 35b can support the housing 10 to allow movement of the housing 10 in the X-axis direction. In one example, four or more supports 35a may be aligned in the X-axis direction, and four or more supports 35b may be aligned in the X-axis direction.

The shapes of the frames 33a and 33b in FIG. 7 are not limited to the above example, but may be any shapes that can fix the guide rails 32a and 32b or the guide rails 34a and 34b to the vehicle body 101. In one example, in a cross section perpendicular to the X-axis direction, each of the frames 33a and 33b may have a U shape that is open in the Y-axis direction.

The power converters 1 to 7 may each be installable on an AC feeding railway vehicle, rather than on a DC feeding railway vehicle. When any one of the power converters 1 to 7 is installed on an AC feeding railway vehicle, the propulsion control device 100 may further include, in addition to the components illustrated in FIG. 1, a transformer that lowers the voltage of the AC power received by the current collector from an electrical substation through a power line and a converter that converts the resulting lower voltage AC power to DC power.

The power converters 1 to 7 may be installed on any movable body other than a railway vehicle, such as an automobile and an aircraft.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1, 2, 3, 4, 5, 6, 7 Power converter
10 Housing
10a, 10b, 10c Surface
10d, 10e Groove
11 Cooler
21a, 21b, 22a, 22b, 25a Column
23a, 23b, 24a, 24b Hanger
31a, 31b, 32a, 32b, 34a, 34b, 36a, 36b Guide rail
33a, 33b Frame
35a, 35b Support
51 Power conversion circuit
52 Control circuit
53 Discharge circuit
91 Electric motor
92 Dolly cart
100 Propulsion control device
100a, 100b Terminal
101 Vehicle body
FC1 Filter capacitor
FL1 Filter reactor
MC1 Contactor
R11 Charging resistor
R12 Discharge resistor
SW11 First switch
SW12 Second switch

1. A vehicle power converter installable on a railway vehicle, the vehicle power converter comprising:
a housing accommodating a power conversion circuit;
an engagement member fixed to a vertically upward surface of the housing and a surface of the housing intersecting with a traveling direction of the railway vehicle; and
a guide attachable under a floor of a vehicle body of the railway vehicle to extend in a width direction of the vehicle body, the guide having a shape engageable with the engagement member and supporting the engagement member to allow movement of the engagement member in the width direction.

2. (canceled)

3. The vehicle power converter according to claim 1, wherein
the engagement member includes a pair of columns extending in the width direction.

4. The vehicle power converter according to claim 1, wherein
the engagement member includes a plurality of hangers aligned in the width direction and in a traveling direction of the railway vehicle.

5. The vehicle power converter according to claim 1, wherein
the guide includes a pair of guide rails extending in the width direction.

6. The vehicle power converter according to claim 5, wherein
each of the pair of guide rails has a T-shaped cross section perpendicular to the width direction.

7. The vehicle power converter according to claim 5, wherein
the guide includes a pair of frames attachable to the vehicle body, and the pair of guide rails are fixed to the pair of frames.

8. The vehicle power converter according to claim 5, wherein
each of the pair of guide rails has an end closer to the vehicle body fixable to the vehicle body and another end farther from the vehicle body supporting the engagement member.

9. The vehicle power converter according to claim 1, wherein
the guide includes a plurality of supports aligned in the width direction and in a traveling direction of the railway vehicle, and each of the plurality of supports has an end closer to the vehicle body fixable to the vehicle body and another end farther from the vehicle body supporting the engagement member.

10. The vehicle power converter according to claim 1, wherein
the engagement member has a T-shaped cross section perpendicular to the width direction.

11. The vehicle power converter according to claim 1, wherein
the housing is waterproof and dustproof.
